(19) United States
(12) Patent Application Publication
(10) Pub. No.: US 2024/0097405 A1
(43) Pub. Date: Mar. 21, 2024

(54) ALL-INTEGRATED COMPLEX SIGNAL GENERATION AND PROCESSING

(71) Applicant: California Institute of Technology, Pasadena, CA (US)

(72) Inventors: Aroutin Khachaturian, Tujunga, CA (US); David Baum, Pasadena, CA (US); Seyed Ali Hajimiri, La Canada, CA (US)

(73) Assignee: California Institute of Technology, Pasadena, CA (US)

(21) Appl. No.: 18/470,945

(22) Filed: Sep. 20, 2023

Related U.S. Application Data
(60) Provisional application No. 63/408,403, filed on Sep. 20, 2022.

(51) Int. Cl. H01S 5/40; G01S 7/4911; H01S 5/026; H01S 5/06

(52) U.S. Cl. CPC H01S 5/4025; G01S 7/4911; H01S 5/026; H01S 5/0618

(57) ABSTRACT

An integrated photonic architecture for coherent signal generation and processing. This architecture can enhance coherent transceiver performance for many applications, including remote sensing, LiDAR, high-speed data communication, and high performance computing.

### CROSS REFERENCE TO RELATED APPLICATIONS

This application claims the benefit under 35 U.S.C. Section 119(e) of U.S. Provisional Application No. 63/408,403, filed Sep. 20, 2022, by Aroutin Khachaturian, David Baum, and Seyed Ali Hajimiri, entitled “ALL INTEGRATED COMPLEX SIGNAL GENERATION AND PROCESSING,” which application is incorporated by reference herein.

### BACKGROUND OF THE INVENTION

### 1. Field of the Invention

The present disclosure relates to photonic integrated circuits for complex signal generation and methods of making and using the same.

### 2. Description of the Related Art

Many photonic systems rely on high-performance coherent signal generation, modulation, and amplification. In typical InP processes, the laser linewidth requirement is insufficient for most coherent processing applications. Furthermore, subsequent coherent signal modulations degrade the output power of the laser and reduce the system sensitivity. What is needed are improved methods of coherent signal modulation that do not degrade the laser output. The present disclosure satisfies this need.

### SUMMARY OF THE INVENTION

The present disclosure describes a coherent signal generation architecture capable of reducing the linewidth of a laser and/or modulating the signal with high output optical power. This architecture can enhance coherent transceiver performance for many applications, including but not limited to, remote sensing, LiDAR, high-speed data communication, and high performance computing.

Embodiments include, but are not limited to, the following.

1. A photonic integrated circuit, comprising:
a linewidth reducing circuit comprising an output; and
an amplifier circuit, connected to the output, comprising:
a power splitter comprising a first array of n waveguides distributing power of signal, when received from the output, into a plurality of n split output signals so that the i^{th} one of the split signals is transmitted in the i^{th} one of the waveguides (for 1<i≤n); and
a first plurality of n amplifiers, wherein the i^{th} h one of the amplifiers is connected to the i^{th} one of the waveguides to amplify the i^{th} one of the split signals to form i^{th} th amplified signal of a plurality of n amplified signals.

2. The photonic integrated circuit of clause 1, wherein the linewidth reducing circuit is coupled to, or comprises, a modulator modulating an input signal to form the signal.

3. The photonic integrated circuit of clause 2, wherein the modulator comprises an IQ coherent modulator, an amplitude modulator, or a phase modulator.

4. The photonic integrated circuit of clause 2, wherein the modulator is programmable to modulate the input signal with a waveform having a phase and/or amplitude for a remote sensing or LIDAR application, encoding data in a communication or computing application, or generating and/or processing an arbitrary complex waveform.

5. A chip comprising the photonic integrated circuit of clause 2, comprising:
an input;
a coupler for coupling the signal from the linewidth reducing circuit to a second signal received at the input;
a second modulator modulating the second signal, when received from the coupler, to form a modulated second signal; and
a plurality of output ports outputting the amplified signals and the modulated second signal off the chip.

6. A LIDAR system comprising the chip of clause 5.

7. The photonic integrated circuit of clause 1, wherein the linewidth reducing circuit comprises:
a first coupler having a first coupler input, a first coupler output, and a second coupler output, the first coupler coupling an input signal into a first portion at the first coupler output and a second portion at the second coupler output;
a delay line or feedback mechanism delaying the first portion, when received from the first coupler output, with respect to the second portion so as to form a delayed portion; and
a mixer mixing the delayed portion with the second portion, when received from the second coupler output, to form an error signal corresponding to a comparison between a frequency of the delayed portion and a frequency of the second portion; and wherein the error signal can used as feedback to control a frequency of a laser outputting the input signal.

8. The photonic integrated circuit of clause 7, wherein the first coupler comprises a multi-mode interferometer (MMI) coupler.′

9. The photonic integrated circuit of clause 7, wherein the feedback mechanism comprises a resonator or a Pound-Drever-Hall system.

10. A system comprising:
the photonic integrated circuit of clause 7 comprising or coupled to the laser; and
a laser control circuit controlling an electrical current modulating the input signal comprising a laser beam outputted from the laser, wherein the laser control circuit uses the feedback so as to reduce a linewidth of the laser beam.

11. The photonic integrated circuit of clause 7, wherein the mixer comprises an IQ coherent mixer.

12. A system comprising the photonic integrated circuit of clause 1, further comprising:
a second array of n waveguides comprising a first side connected to the amplifier circuit and a junction connecting the n waveguides in the second array at a second side, wherein:
the i^{th} waveguide in the second array is coupled to the i^{th} one of the amplifiers so that the amplified signals are coherently combined in the junction.

13. A single chip comprising the system of clause 12.

14. The system of clause 12 comprising a first chip comprising the photonic integrated circuit and a second chip comprising the second array of n waveguides.

15. A chip comprising indium phosphide comprising the photonic integrated circuit of clause 1 patterned in the indium phosphide.

16. A photonic integrated circuit, comprising:
a first coupler having a first coupler input, a first coupler output, and a second coupler output, the first coupler coupling an input signal into a first portion at the first coupler output and a second portion at the second coupler output;
a delay line or feedback mechanism coupled to the first coupler and delaying the first portion, when received from the first coupler output, with respect to the second portion so as to form a delayed portion; and
a mixer mixing the delayed portion with the second portion, when received from the second coupler output, to form an error signal corresponding to a comparison between a frequency of the delayed portion and a frequency of the second portion; wherein the error signal can be used as feedback to control a frequency of a laser outputting the input signal.

17. The photonic integrated circuit of clause 15, wherein the first coupler comprises a multi-mode interferometer (MMI) coupler.

18. A photonic integrated circuit, comprising:
an input for a coherent receiver signal;
a laser;
a multimode interference coupler having a first input for receiving the coherent receiver signal; a second output for receiving to a laser signal outputted from the laser; a first output; and a second output;
a first modulator connected to the first output modulating the coherent receiver signal, when received, to form a modulated receiver signal;
a second modulator connected to the first modulator and the second output for modulating the laser signal when received from the second output;
a receiver amplifier connected to the first modulator for amplifying the modulated receiver signal; and
an amplifier circuit comprising:
   a power splitter distributing power of a signal received from second modulator, into a plurality of n split signals so that the i^{th} one of the split signals is transmitted in the i th one of the waveguides (for 1<i≤n); and
   a plurality of n amplifiers, wherein the i^{th} one of the amplifiers is connected to the i^{th} one of the waveguides to amplify the i^{th} one of the split signals to form an i^{th} amplified signal of a plurality of n amplified signals; and a plurality of output ports for outputting each of the amplified signals.

19. The photonic integrated circuit of clause 18 configured for LIDAR.

20. The photonic integrated circuit of clause 1 configured for generating and/or processing and outputting an arbitrary complex waveform.

### BRIEF DESCRIPTION OF THE DRAWINGS

Referring now to the drawings in which like reference numbers represent corresponding parts throughout:

FIG. 1: Schematic of a photonic integrated circuit design wherein the signal is generated on-chip using InP integrated laser. The SSB modulator modulates the output signal with a complex RF signal (phase and amplitude). The main fraction of the signal is amplified and coupled to outside the chip. The secondary output is mixed using an on-chip IQ coherent photonic mixer with a delayed version of the output for laser linewidth control. The optical delay can come from on-chip delays or off-chip delays.

FIG. 2: Schematic of a photonic integrated circuit design wherein the coherent signal is either generated externally or with an on-chip laser. Two phase modulators encode the coherent signal with desired RF waveform. Output modulated signals are amplified using integrated SOA and coupled to outside the chips via edge-couplers.

FIGS. 3A-3B: Schematic of multi-path signal amplification and recombination. The recombination can happen on another integrated photonic chip (FIG. 3A) or on the same die (FIG. 3B).

FIG. 4A. Flowchart illustrating a method of making a photonic integrated circuit.

FIG. 4B. Schematic of an indium phosphide (InP) platform processing for the PIC.

FIG. 5. MMI coupler according to one or more embodiments.

FIG. 6. Example In Phase and Quadrature (IQ) mixer according to one or more embodiments.

FIG. 7. IQ modulator according to one or more embodiments.

FIG. 8. Hardware environment according to one or more embodiments.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

### Laser Linewidth Enhancement

An embodiment of the present invention comprises an architecture that performs a linewidth reduction of an (e.g., on-chip) laser using entirely integrated photonics in an InP process (for example). The on-chip laser output is coherently mixed with a delayed version of itself, providing a frequency error signal. An electrical servoing circuit uses the error signal to actively control the laser frequency, reducing the linewidth. The delayed signal can be obtained through either an on-chip delay line or an off-chip feedback mechanism.

In one implementation, an IQ coherent modulation [1] and an IQ coherent mixer [2] for signal downconversion is incorporated. The outputs of the IQ coherent mixer serve as feedback signals for the laser. They are used to program the signal modulation block to reduce the laser linewidth. Additionally, the architecture can incorporate the Pound-Drever-Hall technique or other feedback and feed-forward linewidth reduction techniques in conjunction with its existing feedback to reduce the laser linewidth further.

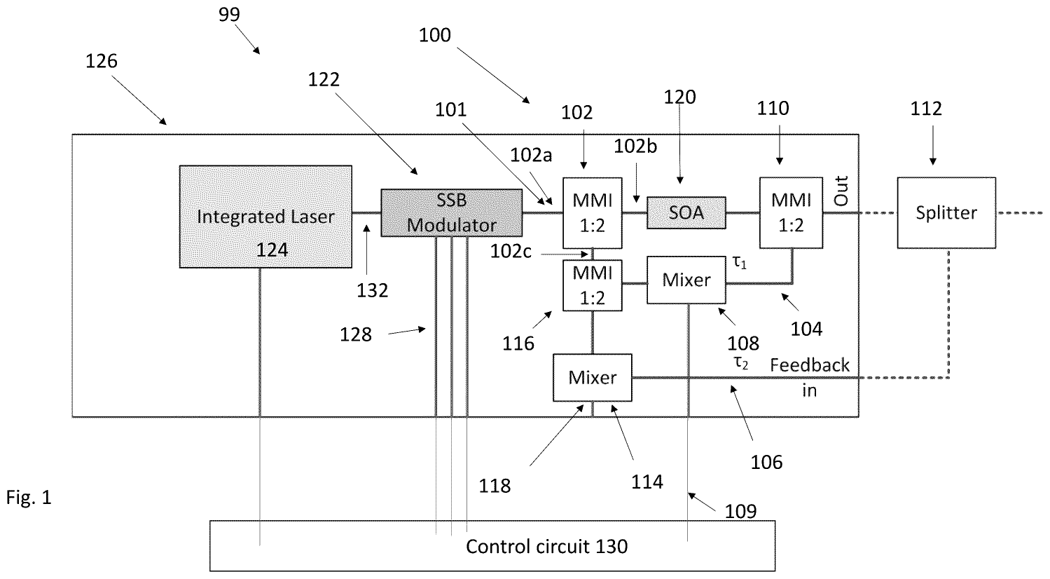

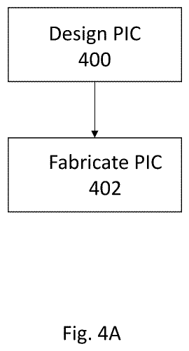

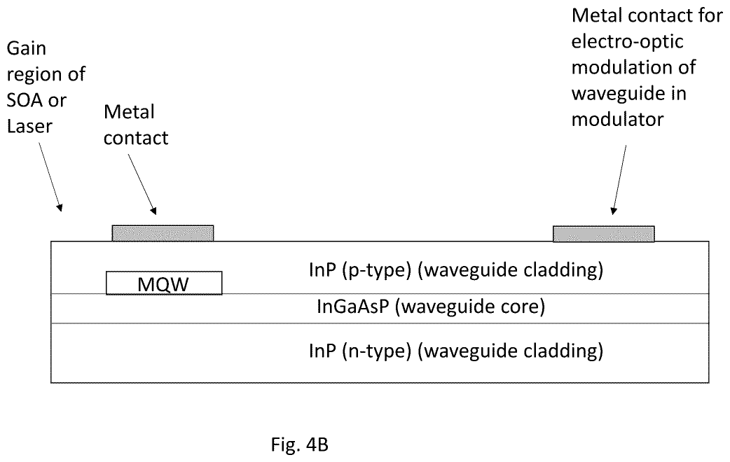

FIG. 1 illustrates an embodiment of a linewidth reducing circuit 100 comprising a first coupler 102 (e.g., multi-mode interferometer MMI coupler, e.g., as illustrated in FIG. 4) having a first coupler input 102a, a first coupler output 102b, and a second coupler output 102c. The first coupler 102 couples an input signal 101 into a first portion at the first coupler output 102b and a second portion at the second coupler output 102c. The linewidth reducing circuit further comprises at least one of a delay line 104 or feedback mechanism 106 coupled to the first coupler and delaying the first portion, when received from the first coupler output, with respect to the second portion, so as to form a delayed portion. In one or more embodiments, the feedback mechanism requiring a delay comprises a broadband physical delay such as long on-chip waveguide or off-chip fiber or a narrowband resonance based delay.

The linewidth reducing circuit further comprises a first mixer 108 mixing the delayed portion with the second portion, when received from the second coupler output, to form a first error signal 109 corresponding to a comparison between a frequency of the delayed portion and a frequency of the second portion. The error signal can be used as feedback to control a frequency of a laser outputting the input signal to the linewidth reducing circuit.

In the embodiment of FIG. 1, the photonic integrated circuit further comprises a second coupler 110 for tapping a third portion from the first portion, so that the third portion may be used for further processing off chip and/or delayed using the feedback mechanism 106. In the case where the third portion is used for delay using feedback mechanism 106 and processing, a splitter 112 is used to further power split the third portion.

In the embodiment of FIG. 1, the photonic integrated circuit further comprises a second mixer 114 mixing the delayed third portion (delayed using the feedback mechanism 106) with the second portion (received from the first coupler 102 via a third coupler 116). The second mixer 114 outputs a second error signal 118 corresponding to a comparison between a frequency of the delayed third portion and a frequency of the second portion. The second error signal can be used as feedback (in combination or independently of the first error signal) to control a frequency of a laser outputting the input signal to the linewidth reducing circuit.

An amplifier 120 can be used to amplify the first portion before application of the delay.

The photonic integrated circuit of FIG. 1 further comprises a modulator 122 connected to the first coupler input. The modulator modulates the signal outputted from a laser 124 (which may be integrated on the same chip 126 as the photonic integrated circuit) to form the input signal inputted to the first coupler input. Example modulators comprise, but are not limited to, an IQ coherent modulator, an amplitude modulator, or a phase modulator.

As known in the art, the phase modulator and amplitude modulator may comprise a material (e.g., liquid crystal or nonlinear material, or electro-optic material, or thermo-optic material) thermally or electrically coupled to an electrode, wherein application of a voltage to the electrode (via bias lines 128) controls, e.g., resistive heating, piezoelectric actuation, bi refringence, or electro-optic actuation of the material so as to control a phase or amplitude of the electromagnetic field (signal beam) passing through the material. Such modulators can be coupled to waveguides carrying the electromagnetic field (signal beam), e.g., in an interferometer, to further modulate the phase or amplitude.

In one or more embodiments, delayed and non delayed portions are mixed to form a signal corresponding to a comparison of the frequencies of the delayed and non delayed portions. The photonic integrated circuit comprises or is connected to a servo circuit including a comparator wherein the signal is compared to a set value to generate an error signal (difference between set value and signal); and negative feedback (e.g., using an operational amplifier) to the current driving the laser, wherein the negative feedback to the current reduces the error signal and therefore the linewidth of the laser. In another embodiment, a feed forward linewidth reduction method is used wherein the phase of the signal (output signal) is corrected based on the output of the comparator.

A laser control circuit 130 may be included on or off chip for controlling an electrical current or voltage (provided via bias lines 132) to power or modulate the laser. The current or voltage modulates the input signal comprising a laser beam outputted from the laser using the feedback, so as to reduce a linewidth of the laser beam.

### Signal Modulation and Boost Amplifiers

The low linewidth output of the laser can be modulated using photonic integrated modulators (phase modulators, amplitude modulators, or SSB modulators) for the desired application. For LiDAR applications, the signal can be modulated with FMCW RF signals in conjunction with a coherent receiver for range and velocity measurement. The modulated output signal of the laser can be amplified using an integrated SOA to the desired output power. However, due to the saturation power limitation of the SOAs, the maximum power of an individual SOA is insufficient for many high-performance applications.

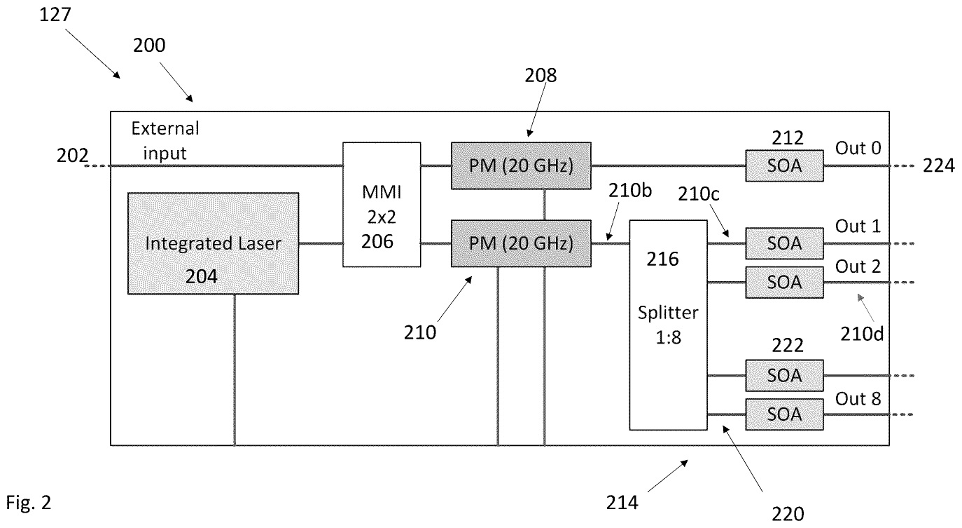

FIG. 2 illustrates a photonic integrated circuit 200 comprising an input 202 for a coherent receiver signal; a laser 204; a multimode interference coupler 206 (or other coupler) having a first input for receiving the coherent receiver signal; a second output for receiving a laser signal outputted from the laser; a first output; and a second output; a first modulator 208 (e.g., phase modulator PM) connected to the first output for modulating the coherent receiver signal to form a modulated receiver signal; a second modulator 210 connected to the first modulator 108 and the second output for modulating the laser signal; a receiver amplifier 212 connected to the first modulator for amplifying the modulated receiver signal; and an amplifier circuit 214.

In one or more embodiments, the MMI 2×2 is a low loss coupler that allows user to select on-chip coherent source, external source, or both simultaneously. Two modulators can allow for independent RF modulation of both paths. For LiDAR applications, this means different modulation waveforms for the transmit path and the reference path.

The amplifier circuit 214 comprises a power splitter 216 comprises a first array of n waveguides 220 distributing the power of an signal, when received from the output of the second modulator, into a plurality of n split output signals so that the i^{th} one of the split output signals is transmitted in the i^{th} one of the waveguides (for 1<i≤n). The amplifier circuit further comprises a first plurality of n amplifiers 222, wherein the i^{th} one of the amplifiers is connected to the i^{th} one of the waveguides to amplify the i^{th} one of the split signals to form an i^{th} amplified signal of a plurality of n amplified signals. The power in each of the split signals is below a saturation level of each of the amplifiers (which may comprise a semiconductor optical amplifier SOA).

The circuit further comprises a plurality of output ports 224 for outputting each of the amplified signals.

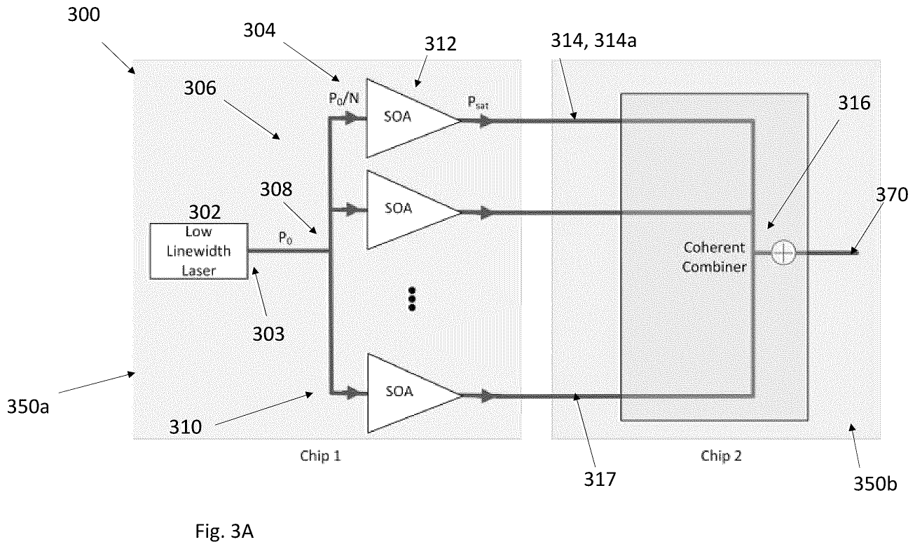

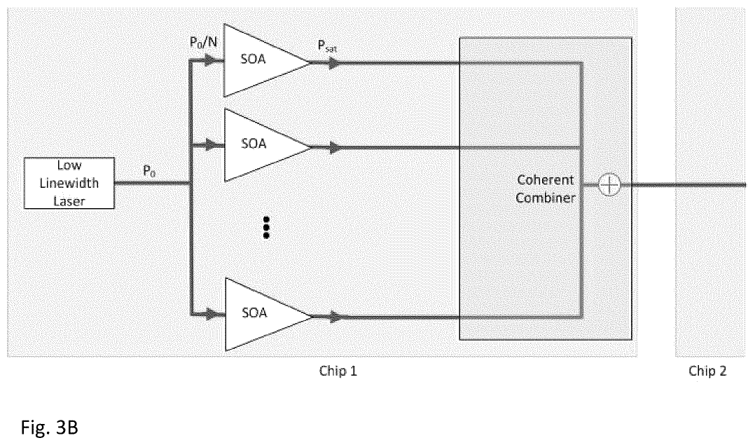

FIG. 3 illustrates another multi-path signal amplification scheme where the limited output power of the laser is split into N paths, amplified to the saturation power with integrated SOAs, and coherently combined to achieve a higher total output power. In one embodiment, the SOA outputs are combined on the same InP chip and coupled using a single output to the other blocks in the system (FIG. 3(b)). In another embodiment, the SOA outputs are first coupled to the other integrated photonic chip using parallel output ports via a fiber array or directly via edge coupler or evanescent couplers. Afterward, the coherent combining is performed on the secondary chip, which could be a silicon photonic chip or another InP chip (FIG. 3(a)). The advantage of the second method is that it relaxes the power tolerance requirement on the input waveguides, couplers, fibers, and packaging.

FIG. 3 illustrates an embodiment of a photonic integrated circuit 300 comprising a low linewidth laser source 302 (laser or output from a linewidth reducing circuit 100) having an output 303 connected to an amplifier circuit 304. The amplifier circuit comprises a power splitter 306, comprising a junction 308 splitting into a first array 310 of n waveguides. The junction splits a signal, when received from the output 303, into a plurality of n split output signals so that the i^{th} one of the split output signals (for 1<i≤n) is transmitted in the i^{th} one of the waveguides. The amplifier circuit further comprises first plurality of n amplifiers 312, wherein the i^{th} one of the amplifiers is connected to the i^{th} one of the waveguides to amplify the i^{th} one of the split signals to form an i^{th} amplified signal of a plurality of n amplified signals. The power in each of the split signals is below a saturation level of each of the amplifiers (which may comprise a semiconductor optical amplifier).

FIG. 3 further illustrates a second array 314 of n waveguides comprising a first side connected to the amplifier circuit and a second junction 316 connecting the n waveguides in the second array at a second side. The i^{th} waveguide in the second array is coupled to the i^{th} one of the amplifiers so that the amplified signals are coherently combined in the junction 316. FIG. 3a illustrates the embodiment wherein the coherent combiner and power splitter are on the same chip, FIG. 3b illustrates the embodiment wherein the coherent combiner and power splitter are on separate chips.

In some embodiments, a basic coherent combiner is the reverse of a splitter tree. In other embodiments, a more advanced coherent combiner can adjust the relative amplitude and phase of different paths before combining to improve combining by calibrating for fabrication and assembly imperfections. In some embodiments, the coherent combiner comprises the waveguides connected to phase/amplitude modulators to correct phase and/or amplitude.

Although FIGS. 1-3 illustrate waveguides 314 connecting various optical components such as modulators, lasers, and amplifiers, these waveguides can be more generally paths for transmitting the signals carried by electromagnetic radiation, waves, or fields (e.g., having any wavelength including, but not limited to, wavelengths in a range from visible to infrared. The electromagnetic radiation/waves/fields can be modulated with signals (e.g., waveforms) at various frequencies including, but not limited to, radio frequencies.

### Complex Waveform Generators and Processors

In one or more embodiments, the photonic integrated circuits, systems, or chips described herein comprise, or are components of, a complex waveform generator or processor. More specifically, electromagnetic radiation outputted from the laser and processed by the photonic integrated circuits described herein can be modulated (by the modulators) with signals comprising any complex waveform 370 (e.g., any arbitrary superposition of sine waves and/or phase and/or amplitude), so that the outputs of the photonic integrated circuits may comprise electromagnetic (e.g., laser) beam(s) comprising any arbitrary complex waveform with reduced linewidth and tailored power.

### Process Steps

FIG. 4A is a flowchart illustrating a method of making a photonic integrated circuit according to one or more embodiments.

Block 400 represents designing the photonic integrated circuit (PIC).

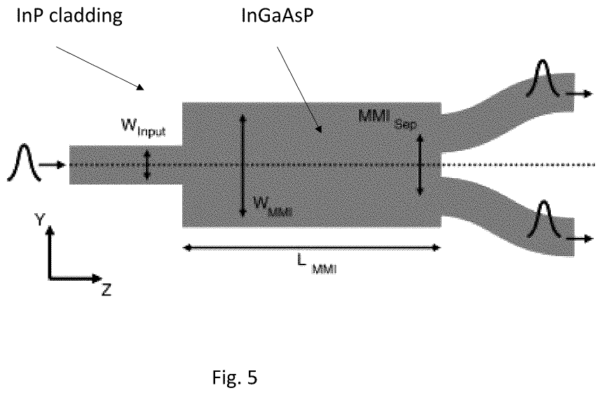

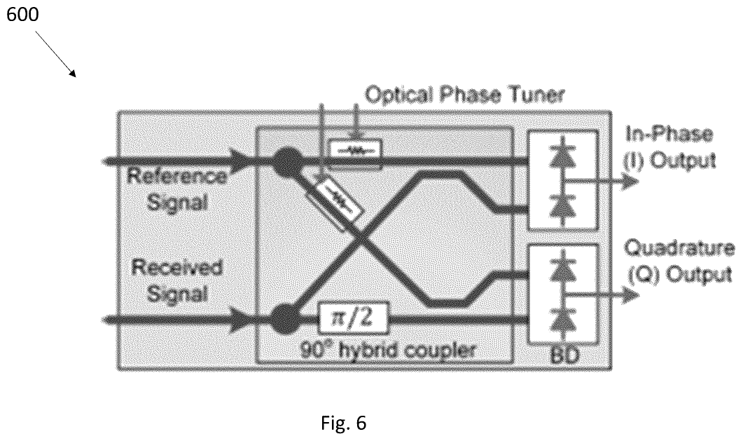

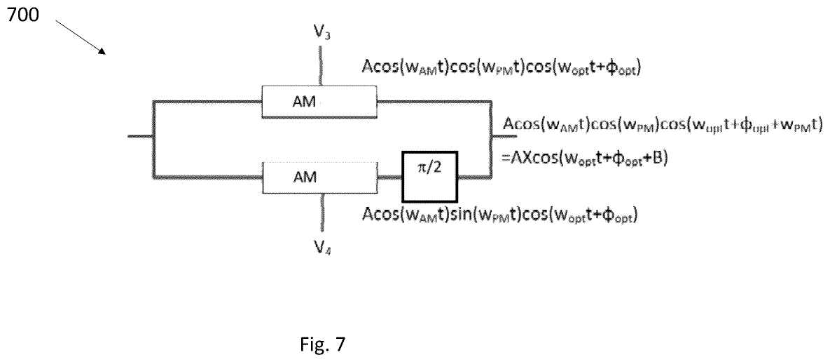

Block 402 represents fabricating the photonic integrated circuit. In one embodiment, the step comprises obtaining a substrate (e.g., comprising InP) and growing, doping, and photolithographically patterning the resulting structure to form the photonic integrated circuit. FIG. 4B illustrates an embodiment based on the InP platform, wherein the waveguides comprise an InGaAsP core clad by InP (to form a clad waveguide); the laser comprises a distributed bragg reflector laser comprising mirrors comprising gratings etched into the waveguide core on either side of a gain region comprising an InGaAsP/InP multiquantum well on the waveguide core; the power splitters and power combiners comprise directional couplers comprising the clad waveguides coupled by a gap in the coupling region before the waveguides separate (splitter) or combine (combiner), the semiconductor optical amplifiers (SOA) comprise the clad waveguide and the multiquantum wells (MQW) which may be optionally coupled to an electrical contact for gain control; the modulators comprise the clad waveguides coupled to an electrical contact for modulating transmission in the waveguide; and the MMI couplers comprise the clad waveguides patterned as shown in FIG. 5. The InP cladding layers on either side of the core can comprise opposite doping (n-type v. p-type) to provide electrically excited carrier excitation between the valence and conduction band, so as to excite optical recombination in the laser as is known in the art). Metal contact pads can be provided on the top surface of the InP/InGaAsP structure to provide the electrical contacts for biasing and electrooptical modulation to the PIC components as needed. An example process for fabricating lasers, modulators, power splitters, SOAs, and combiners is described in [3]. Further information on design and fabrication of In phase and Quadrature (IQ) modulators and mixers can be found in [4]. FIG. 6 and FIG. 7 illustrate an example IQ mixer and an example IQ modulator, respectively, where
PM is a phase modulator,
AM is an amplitude modulator,
π/2 is a 90° phase shifter,
V1, V2, V3, V4 are voltage control signals,
A is the amplitude,
B is a phase shift,
X is a constant,
wₒₚₜ is the frequency of the signal beams/optical carrier,
ϕₒₚₜ is the phase of the optical carrier,
w_{PM} is the frequency of the phase modulated signal,
ϕ_{PM} is the phase of the phase modulated signal,
w_{AM} is the frequency of the amplitude modulated signal,
ϕ_{AM} is the phase of the amplitude modulated signal, and
t is time.

Other material platforms/systems can be used, e.g., but not limited to wherein waveguides are formed by cladding a higher refractive index core in a lower refractive index cladding.

The PIC can be coupled to a processor, computer, or other integrated circuit (e.g., FPGA, or ASIC) for controlling the PIC via the biasing of the electrical contacts, to provide processing or complex waveform generation capabilities as described herein.

The PIC fabricated by the method illustrated in FIG. 4 can be implemented in many ways including, but not limited to, the following (referring also to FIGS. 1-8).

1. A photonic integrated circuit 99, comprising:
a linewidth reducing circuit 100 comprising an output 303; and
an amplifier circuit 120, 304, connected to the output, comprising:
a power splitter 306 comprising a first array 310 of n waveguides 317 configured for distributing power of a signal Po, e.g., when received from the output, into a plurality of n split output signals so that the i^{th} one of the split signals Po/Nis transmitted in the i^{th} one of the waveguides (for 1<i≤n and n is an integer); and
a first plurality 312 of n amplifiers, wherein the i^{th} one of the amplifiers is connected to the i^{th} one of the waveguides and is configured to amplify the i^{th} one of the split signals to form an i^{th} amplified signal 314a of a plurality of n amplified signals.

2. The photonic integrated circuit of clause 1, wherein the linewidth reducing circuit is coupled to, or comprises, a modulator 122 configured for modulating an input signal to form the signal.

3. The photonic integrated circuit of clause 2, wherein the modulator comprises at least one of an IQ coherent modulator 700, an amplitude modulator (AM), or a phase modulator (PM).

4. The photonic integrated circuit of clause 2 or 3, wherein the modulator is programmable to/configured to modulate the input signal with a waveform having a phase and/or amplitude for a remote sensing or LIDAR application, or encoding data in a communication or computing application, or for generating and/or processing an (e.g., arbitrary) complex waveform.

5. A chip 126, 127 comprising the photonic integrated circuit of any of the clauses 1-4, comprising:
an input 202;
a coupler 206 configured for coupling the signal from the linewidth reducing circuit to a second signal (e.g., a coherent receiver) received at the input;
a second modulator 208 configured for modulating the second signal, when received from the coupler, to form a modulated second signal; and
a plurality of output ports 224 configured for outputting the amplified signals and the modulated second signal off the chip.

6. A light detection and ranging (LIDAR) system comprising the chip of clause 5.

7. The photonic integrated circuit of any of the clauses 1-6, wherein the linewidth reducing circuit comprises:
a first coupler 102 having a first coupler input 102a, a first coupler output 102b, and a second coupler output 102c, the first coupler configured for coupling an input signal 101 into a first portion at the first coupler output and a second portion at the second coupler output;
a delay line 104 or feedback mechanism configured for delaying the first portion, when received from the first coupler output, with respect to the second portion so as to form a delayed portion; and
a mixer 108 configured for mixing the delayed portion with the second portion, when received from the second coupler output, to form an error signal 109 corresponding to a comparison between a frequency of the delayed portion and a frequency of the second portion; and wherein the error signal can used as feedback to control a frequency of a laser 124 (e.g., integrated laser) outputting the input signal.

8. The photonic integrated circuit of clause 7, wherein the first coupler comprises a multi-mode interferometer (MMI) coupler.′

9. The photonic integrated circuit of clause 7, wherein the feedback mechanism comprises at least one of a resonator, a Pound-Drever-Hall system, a broadband physical delay such as long on-chip waveguide or off-chip fiber, or a narrowband resonance based delay.

10. A system comprising:
the photonic integrated circuit of any of the clauses 7-9 comprising or coupled to the laser 124; and
a laser control circuit 130 configured for controlling an electrical current modulating the input signal comprising a laser beam 132 outputted from the laser, wherein the laser control circuit uses the feedback so as to reduce a linewidth of the laser beam.

11. The photonic integrated circuit of any of the clauses 7-10, wherein the mixer comprises an IQ coherent mixer 600.

12. A system comprising the photonic integrated circuit of any of the clauses 1-11, further comprising:
a second array 314 of n waveguides comprising a first side connected to the amplifier circuit and a junction 316 connecting the n waveguides in the second array at a second side, wherein:
the i^{th} waveguide in the second array is coupled to the i^{th} one of the amplifiers so that the amplified signals are coherently combined in the junction.

13. A single chip comprising the system of clause 12.

14. The system of clause 12 comprising a first chip comprising the photonic integrated circuit and a second chip comprising the second array of n waveguides.

15. A chip comprising indium phosphide comprising the photonic integrated circuit of any of the clauses 1-14 patterned in the indium phosphide.

16. A photonic integrated circuit 99, comprising:
a first coupler 102 having a first coupler input 102a, a first coupler output 102b, and a second coupler output 102c, the first coupler configured for coupling an input signal 101 into a first portion at the first coupler output and a second portion at the second coupler output;
a delay line 104 or feedback mechanism coupled to the first coupler and configured for delaying the first portion, when received from the first coupler output, with respect to the second portion so as to form a delayed portion; and
a mixer 108 configured for mixing the delayed portion with the second portion, when received from the second coupler output, to form an error signal 109 corresponding to a comparison between a frequency of the delayed portion and a frequency of the second portion; wherein the error signal can be used as feedback to control a frequency of a laser outputting the input signal.

17. The photonic integrated circuit of clause 16, wherein the first coupler comprises a multi-mode interferometer (MMI) coupler.

18. A photonic integrated circuit 200, comprising:
an input 202 for a coherent receiver signal;
a laser 204;
a multimode interference (MMI) coupler 206 having a first input configured for receiving the coherent receiver signal; a second output configured for receiving to a laser signal outputted from the laser; a first output; and a second output;
a first modulator 208 connected to the first output and configured for modulating the coherent receiver signal, when received, to form a modulated receiver signal;
a second modulator 210 connected to the first modulator and the second output for modulating the laser signal when received from the second output;
a receiver amplifier 212 connected to the first modulator for amplifying the modulated receiver signal; and
an amplifier circuit 214 comprising:
   a power splitter 216 configured for distributing power of a signal 210a received from the second modulator, into a plurality of n split signals 210c so that the i^{th} one of the split signals is transmitted in the i^{th} one of the waveguides (for 1<i≤n); and
   a plurality of n amplifiers 222, wherein the i^{th} one of the amplifiers is connected to the i^{th} one of the waveguides to amplify the i^{th} one of the split signals to form an i^{th} amplified signal of a plurality of n amplified signals; and a plurality of output ports 224 for outputting each of the amplified signals 210d.

19. An arbitrary complex waveform generator 802 or processor 800 comprising the photonic integrated circuit of any of the clauses 1-18 or the photonic integrated circuit of any of the clauses 1-18 configured as an arbitrary complex waveform 370 generator or processor.

20. All control circuitry controlling bias to the modulators and laser of any of the clauses 1-19 can be implemented using programmed/appropriately configured processors/computer 800 or ASIC or FPGA.

### Hardware Environment

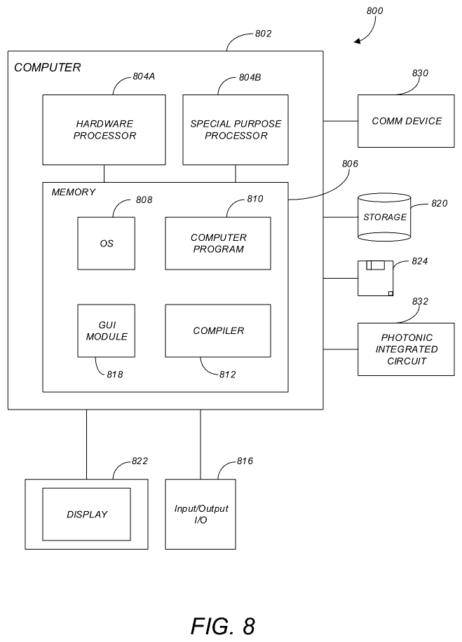

FIG. 8 is an exemplary hardware and/or software environment 800 (referred to as a computer-implemented system and/or computer-implemented method) used to implement one or more embodiments of the invention and which may be coupled to the photonic integrated circuits 832 described herein. The hardware and software environment includes a computer 802 and may include peripherals. Computer 802 may be a user/client computer, server computer, or may be a database computer. The computer 802 comprises a hardware processor 804A and/or a special purpose hardware processor 804B (hereinafter alternatively collectively referred to as processor 804) and a memory 806, such as random access memory (RAM). The computer 802 may be coupled to, and/or integrated with, other devices, including input/output (I/O) devices such as a keyboard 814, a cursor control device 816

In one embodiment, the computer 802 operates by the hardware processor 804A performing instructions defined by the computer program 810 (e.g., control of the PIC or feedback) under control of an operating system 808. The computer program 810 and/or the operating system 808 may be stored in the memory 806 and may interface with the user and/or other devices to accept input and commands and, based on such input and commands and the instructions defined by the computer program 810 and operating system 808, to provide output and results.

Output/results may be presented on the display 822 or provided to another device for presentation or further processing or action.

Some or all of the operations performed by the computer 802 according to the computer program 810 instructions may be implemented in a special purpose processor 804B. In this embodiment, some or all of the computer program 810 instructions may be implemented via firmware instructions stored in a read only memory (ROM), a programmable read only memory (PROM) or flash memory within the special purpose processor 804B or in memory 806. The special purpose processor 804B may also be hardwired through circuit design to perform some or all of the operations to implement the present invention. Further, the special purpose processor 804B may be a hybrid processor, which includes dedicated circuitry for performing a subset of functions, and other circuits for performing more general functions such as responding to computer program 810 instructions. In one embodiment, the special purpose processor 804B is an application specific integrated circuit (ASIC) or field programmable gate array.

The computer 802 may also implement a compiler 812 that allows an application or computer program 810 written in a programming language to be translated into processor 804 readable code. Alternatively, the compiler 812 may be an interpreter that executes instructions/source code directly, translates source code into an intermediate representation that is executed, or that executes stored precompiled code. After completion, the application or computer program 810 accesses and manipulates data accepted from I/O devices and stored in the memory 806 of the computer 802 using the relationships and logic that were generated using the compiler 812.

In one embodiment, instructions implementing the operating system 808, the computer program 810, and the compiler 812 are tangibly embodied in a non-transitory computer-readable medium, e.g., data storage device 820, which could include one or more fixed or removable data storage devices, such as a zip drive, floppy disc drive 824, hard drive, CD-ROM drive, tape drive, etc. Further, the operating system 808 and the computer program 810 are comprised of computer program 810 instructions which, when accessed, read and executed by the computer 802, cause the computer 802 to perform the steps necessary to implement and/or use the present invention or to load the program of instructions into a memory 806, thus creating a special purpose data structure causing the computer 802 to operate as a specially programmed computer executing the method steps described herein. Computer program 810 and/or operating instructions may also be tangibly embodied in memory 806 and/or data communications devices 830, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 802.

### REFERENCES

The following references are incorporated by reference herein.
[1] Mohamad Hossein Idjadi and Firooz Aflatouni. Wideband laser linewidth reduction using a hybrid integrated phase noise filter. In Optical Fiber Communication Conference (OFC) 2021, page Tu1K.4. Optica Publishing Group, 2021. doi:10.1364/OFC.2021.Tu1K.4. URL http://opg.optica.org/ abstract.cfm?URI=OFC-2021-TulK.4.
[2] Aroutin Khachaturian, Reza Fatemi, and Ali Hajimiri. Iq photonic receiver for coherent imaging with a scalable aperture. IEEE Open Journal of the Solid-State Circuits Society, 1:263-270, 2021. doi:10.1109/OJSSCS.2021.3113264.
[3] Meint Smit, Kevin Williams, Jos van der Tol; Past, present, and future of InP-based photonic integration. APL Photonics 1 May 2019; 4 (5): 050901. https://doi.org/10.1063/1.5087862
[4] U.S. patent application Ser. No. 18/263,283 (entitled COMPLEX WAVEFRONT PHOTONIC TRANSCEIVER PROCESSOR) and US patent Publication No. 2022-0400217 entitled COHERENT PHOTONICS IMAGER WITH OPTICAL CARRIER SUPPRESSION AND PHASE DETECTION CAPABILITY, both by Aroutin Khachaturian and Seyed Hajimiri.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A photonic integrated circuit, comprising:
a linewidth reducing circuit comprising an output; and
an amplifier circuit, connected to the output, comprising:
a power splitter comprising a first array of n waveguides distributing power of signal, when received from the output, into a plurality of n split output signals so that the i^{th} one of the split signals is transmitted in the i^{th} one of the waveguides (for 1<i≤n); and
a first plurality of n amplifiers, wherein the i^{th} one of the amplifiers is connected to the i^{th} one of the waveguides to amplify the i^{th} one of the split signals to form an i^{th} amplified signal of a plurality of n amplified signals.

2. The photonic integrated circuit of claim 1, wherein the linewidth reducing circuit is coupled to, or comprises, a modulator modulating an input signal to form the signal.

3. The photonic integrated circuit of claim 2, wherein the modulator comprises an IQ coherent modulator, an amplitude modulator, or a phase modulator.

4. The photonic integrated circuit of claim 2, wherein the modulator is programmable to modulate the input signal with a waveform having a phase and/or amplitude for a remote sensing or LIDAR application, encoding data in a communication or computing application, or generating and/or processing an arbitrary complex waveform.

5. A chip comprising the photonic integrated circuit of claim 2, comprising:
an input;
a coupler for coupling the signal from the linewidth reducing circuit to a second signal received at the input;
a second modulator modulating the second signal, when received from the coupler, to form a modulated second signal; and
a plurality of output ports outputting the amplified signals and the modulated second signal off the chip.

6. A LIDAR system comprising the chip of claim 5.

7. The photonic integrated circuit of claim 1, wherein the linewidth reducing circuit comprises:
a first coupler having a first coupler input, a first coupler output, and a second coupler output, the first coupler coupling an input signal into a first portion at the first coupler output and a second portion at the second coupler output;
a delay line or feedback mechanism delaying the first portion, when received from the first coupler output, with respect to the second portion so as to form a delayed portion; and
a mixer mixing the delayed portion with the second portion, when received from the second coupler output, to form an error signal corresponding to a comparison between a frequency of the delayed portion and a frequency of the second portion; and wherein the error signal can used as feedback to control a frequency of a laser outputting the input signal.

8. The photonic integrated circuit of claim 7, wherein the first coupler comprises a multi-mode interferometer (MMI) coupler.′

9. The photonic integrated circuit of claim 7, wherein the feedback mechanism comprises a resonator or a Pound-Drever-Hall system.

10. A system comprising:
the photonic integrated circuit of claim 7 comprising or coupled to the laser; and
a laser control circuit controlling an electrical current modulating the input signal comprising a laser beam outputted from the laser, wherein the laser control circuit uses the feedback so as to reduce a linewidth of the laser beam.

11. The photonic integrated circuit of claim 7, wherein the mixer comprises an IQ coherent mixer.

12. A system comprising the photonic integrated circuit of claim 1, further comprising:
a second array of n waveguides comprising a first side connected to the amplifier circuit and a junction connecting the n waveguides in the second array at a second side, wherein:
the i^{th} waveguide in the second array is coupled to the i^{th} one of the amplifiers so that the amplified signals are coherently combined in the junction.

13. A single chip comprising the system of claim 12.

14. The system of claim 12 comprising a first chip comprising the photonic integrated circuit and a second chip comprising the second array of n waveguides.

15. A chip comprising indium phosphide comprising the photonic integrated circuit of claim 1 patterned in the indium phosphide.

16. A photonic integrated circuit, comprising:
a first coupler having a first coupler input, a first coupler output, and a second coupler output, the first coupler coupling an input signal into a first portion at the first coupler output and a second portion at the second coupler output;
a delay line or feedback mechanism coupled to the first coupler and delaying the first portion, when received from the first coupler output, with respect to the second portion so as to form a delayed portion; and
a mixer mixing the delayed portion with the second portion, when received from the second coupler output, to form an error signal corresponding to a comparison between a frequency of the delayed portion and a frequency of the second portion; wherein the error signal can be used as feedback to control a frequency of a laser outputting the input signal.

17. The photonic integrated circuit of claim 16, wherein the first coupler comprises a multi-mode interferometer (MMI) coupler.

18. A photonic integrated circuit, comprising:
an input for a coherent receiver signal;
a laser;
a multimode interference coupler having a first input for receiving the coherent receiver signal; a second output for receiving to a laser signal outputted from the laser; a first output; and a second output;
a first modulator connected to the first output modulating the coherent receiver signal, when received, to form a modulated receiver signal;
a second modulator connected to the first modulator and the second output for modulating the laser signal when received from the second output;
a receiver amplifier connected to the first modulator for amplifying the modulated receiver signal; and
an amplifier circuit comprising:
a power splitter distributing power of a signal received from second modulator, into a plurality of n split signals so that the i^{th} one of the split signals is transmitted in the i^{th} one of the waveguides (for 1<i≤n); and
a plurality of n amplifiers, wherein the i^{th} one of the amplifiers is connected to the i^{th} one of the waveguides to amplify the i^{th} one of the split signals to form an i^{th} amplified signal of a plurality of n amplified signals; and
a plurality of output ports for outputting each of the amplified signals.

19. The photonic integrated circuit of claim 18 configured for LIDAR.

20. The photonic integrated circuit of claim 1 configured for generating and/or processing and outputting an arbitrary complex waveform.
